(19) United States
(12) Patent Application Publication
(10) Pub. No.: US 2009/0267792 A1
(43) Pub. Date: Oct. 29, 2009

(54) Customer supported automatic meter reading method

(76) Inventor: Henry Crichlow, Norman, OK (US)

Correspondence Address: HENRY CRICHLOW, 330 W. GRAY ST., SUITE 504, NORMAN, OK, 73069, US

(21) Appl. No.: 12/383,791

(22) Filed: Mar. 30, 2009

Related U.S. Application Data
(60) Provisional application No. 61/125,341, filed on Apr. 25, 2008.

(51) Int. Cl. G01R 1/00

(52) U.S. Cl. 340/870.02

(57) ABSTRACT

A method is described in which an automatic metering reading (AMR) method is implemented in the utility distribution system. The AMR method comprises a mesh network in which selected customers of the utility company support the network by providing collocated internet access points via the customer's existing internet connections; thus providing AMR data “backhaul”, thereby minimizing the need for the utility to build and deploy all the access points needed to populate the mesh infrastructure network. This customer access point for which the customer is remunerated, in whole or in part by the utility, allows the utility to develop and implement all the network elements to meet the utility AMR needs at a much lower cost. The customer-supported method can allow the utility to efficiently and effectively service its metering needs via the global communications network without a major investment in hardware, software and personnel.

### CROSS REFERENCE TO RELATED APPLICATIONS

This application claims priority from provisional application No. 61/125,341 filed Apr. 25, 2008 by Dr. Henry Crichlow.

### SPECIFICATION

Introduction:

A mesh network is a system of discrete nodes in which information is routed between nodes by means of hopping from one node to another within the system until the final or destination node is reached. The mesh network allows the node system to be continuously reconfigured as needed. In mesh networks each node can be connected to any other node by multiple hops. One critical attribute of mesh networks is that these networks are self-healing and can operate successfully even when multiple nodes become inoperable or when connections break down. All AMR networks need a mechanism to get the meter data transmitted back to the utility company via the global communications network. This route is commonly called the “backhaul”.

A utility company has a large number of customers (investor owned utilities can have as many as 5,000,000). These customers have commodity meters that read, report and provide usage data usually on electric power, gas and water. Other parameters that can be measured include power factor, current, voltage and reactive power. Smaller utility companies have fewer customers, but even the smallest municipal or rural electric companies; can still have between 5,000 and 100,000 customers. Meters are the “cash registers” of the utility company in that unless the amount of commodity used is determined; the utility cannot charge for it, which is detrimental to its revenue stream. Compounding this issue for utilities, in particular smaller operations are the cost associated with meter reading.

There are several concurrent events that are converging to provide a cultural and economic climate in which a solution to the AMR problem is made possible. These events are:
Governmental and regulatory agencies are mandating some form of energy efficiency and control by the utility companies, (US Congress. HR4 HR6), necessitating realtime or near-realtime data monitoring
The development of ubiquitous wireless technology and the Federal Communications Commission is proposing a free national Internet wireless network.
The global communications network and high speed broadband internet connections are becoming increasingly ubiquitous
The rising cost of energy is making personal and business commodity conservation more and more necessary
A growing community awareness that the Internet is a tool to share and collaborate activities

### FIELD OF INVENTION

This invention relates to the automatic meter reading (AMR) function of a utility company wherein the utility has the obligation to read the values of the commodity usage by its customers. Specifically this invention relates to the use of an interconnected wireless mesh network with Internet access points which allow the utility to read the meters over its distribution area. In this invention selected utility customers use their existing Internet connections to support the utility in deploying the access points needed to populate the interconnected network and make the AMR network complete.

### BACKGROUND OF THE INVENTION

Commodity usage data forms the basis of revenue generation for the utility companies. The collection of meter data from electrical energy, water, and gas meters has hitherto been routinely performed by human meter-readers on a monthly basis and today in 2008 there is a concerted effort to read meters by more efficient means. In the USA there is only about a 3% penetration of the existing 265,000,000 electric meters that are read by automatic means, worldwide the percentage penetration is even smaller. For water and gas meter systems the rate of penetration is even lower. The need for AMR is still great and utility companies are trying to meet these needs and to lower their operating costs. This effort is prodded on by government regulation and also by the need to be competitive and by energy conservation.

The current meter reading methodologies are labor intensive, expensive, error prone, inefficient and often provide data and information too late to be a decision making tool. According to US Energy Information Agency publications the cost of managing a metering operation and customer services in a utility is significant. In one NY utility Con Edison, it can cost as much as $1,000,000 a day to provide all the services connected to providing customer and meter service. Coupled to these indirect costs are the extremely high direct costs of fuel for power generation, which is approximately 70% of a utility's operating cost structure. By having commodity usage information in a relevant time period and in a manner to allow optimal decision-making, the utility can save millions of dollars in generation costs, its biggest cost center.

Other economic aspects of AMR involve the need to adequately determine outage at a given location which can have deleterious effects on the customers. In addition there is a need today because of the constant customer mobility in which they change residences many times over a few years creating the need for the utility to connect and disconnect its meters on a continuous basis. A better means for providing these two functions is needed by the utility company today. This is the economic basis for the AMR concepts described in this invention. Better data makes for better decision-making and lower operating costs to benefit the utility owners and their customers.

In the utility companies' prior efforts to update their existing AMR systems, some meters have been enhanced to include radio frequency (RF) transmitter devices and other communication devices to allow meter readers to drive by, walk by or remotely collect data from the modified meters. The current walk-by, drive-by systems though improvements are still archaic compared to the current existing technologies in use in the electronic world.

AMR means today have used wired and wireless networks. Companies have installed devices for radio repeaters and access gateways located on high structures to receive data from updated meters fitted with RF transmitters. Meter data is transmitted from the meters to the repeaters and gateways and ultimately communicated to a central location.

The amount of data read and collected by an AMR device in a utility system varies with the type of customer. Industrial and commercial customers who use more electric power, generally require that data be read more frequently and with more sophisticated devices. Residential customers do not need the same level of sophistication nor the same read frequency. Most regulated utility readings are at most at 15-minute intervals for residential customers and can be less than 1-minute intervals for commercial and industrial customers. The amount of data collected and transmitted is proportionally based on the frequency of reading: for example at 15-minute intervals, during a 24-hour day time period, a residential “read” will have 24×4=96 separate numbers for each “day-read” interval. The size of the digital file to store 96 numbers is quite small; assuming 12 bytes to store each number the file size is 96×12=1,152 bytes. This is a 1.15 KB file to be transmitted through the AMR network to the utility computer servers; this is an extremely small file size in today's computer environment wherein consumers routinely transfer 700 MB sized (700,000,000) graphic files or video movie files from one to the other. Even performing a 1-minute read frequency; the file size is 1,440×12=17,280 bytes, which is still a very small file. These small files can be transmitted in a fraction of a second over existing networks and the typical AMR dataset requires an extremely small amount of bandwidth on existing Internet connection which can routinely transmit at more than 54 Megabits (54,000,000) per second.

In addition, data compression techniques can be utilized to pack the data files to decrease file size and still decrease the time needed for transmission through the network and to the global network via the access points and gateways. This compression can be done invisibly to the utility customer, so an AMR data file can be compressed and be transmitted considerably faster than normally expected.

Furthermore, in the residential network even though the AMR device on location reads the data continuously, actual data transmission is routinely done only once daily to the utility central site. Industrial and commercial customers are transmitted on a more or less real time basis to the central utility site.

Utilizing Automatic Meter Reading (AMR) technologies is a major endeavor by utility companies around the world to read their commodity meters. This effort is driven by the increased costs of operations of utility enterprises and the need for competitiveness in the market place. The technology to read the meter usage is not very sophisticated, it is easily done and generally reliable, the critical need is to get this usage data back to the utility so that its staff can utilize the data to make operational decisions and to timely and effectively bill the customers for usage. The AMR effort can be considered to occur across three different spaces; the customer space, the Internet space and the utility space. Affordable and reliable connections between these spaces are what are required to make a system function efficiently and to provide the seamless integration necessary for a competitive utility.

The customer space comprises all the customers and their meters. The Internet space is the ubiquitous global network that we all depend on to provide electronic and communication services today. The utility space is the domain of the utility company with its decision-making, billing and other operational services. Two of the spaces are already fully connected, the utility and the Internet space, by existing reliable and redundant high-speed broadband connections. The connection between the customer spaces herein referred to as the “backhaul” is not so connected and is the major obstacle to the widespread deployment of the AMR systems.

Companies have tried a host of different alternatives to connect this backhaul to the global communication network. Systems are either wired or wireless. They have ranged from specialized telecom networks to power line carrier (PLC) networks. One particular company CellNET has gone bankrupt after expending $450 million in a matter of months, trying to set up a cellular network to use as a backhaul for AMR data. Other companies have used hardware systems with collectors, repeaters and adapters; on telephone poles, on traffic lights, on electric light poles, on cell towers even on balloons. Each of these approaches is fraught with a multitude of problems including high costs, land availability, zoning restrictions and reliability and maintainability.

Unrecognized in this situation is the fact that today according to published US government data more than 82.5 million broadband connection locations exist across the country and according to PEW Research the current rate of growth is 12% annually. The total number of existing utility meter connections is about 265 million, which have to be read at timely intervals. Furthermore, the amount of digital data, a few kilobytes, in each meter read is extremely small by today's digital file standards. These millions of existing broadband connections afford a vital connection to the global communication network and as such can provide a ready solution to the backhaul quandary if properly implemented. It is one of the objectives of this invention to describe a means for utilizing these existing customer connections as a mini-backhauls which collectively provide the necessary infrastructure for a backhaul system in the AMR networks that is affordable, efficient and reliable.

Current AMR networks reduce human involvement in the process of meter reading, but there are many drawbacks to these systems which can be alleviated by the application of technologies which are routinely available in the electronic world today.

These drawbacks in current networks include:
Installation of fixed networks
Maintenance requirements of these networks
Inability to easily optimize these networks
Difficulty in updating of the networks.
Lack of redundancy
Total cost and installation of operation

Among the technologies that exist today that can improve the AMR operations include:
Wireless mesh networks
Self organizing network protocols
Widely available fast Internet broadband connections
Algorithms for efficient data compression
Fault tolerant network algorithms
Algorithms for transmission collision avoidance
Satellite based network systems
Wifi and Wimax standards based methodologies

By design, mesh networks are different to the typical network architecture in that a full physical connectivity is not required between the node member and every other member of the network for it to function. As long as a node is connected to at least one other node in a mesh network, it will have full connectivity to the entire network because each mesh node transmits data to other nodes in the network as required. Mesh algorithms and protocols can automatically determine the optimal route through the network and if a link becomes disrupted or unusable they can dynamically reconfigure and reorganize the network. This feature of the mesh network and the fact that only a small amount of data needs to be transferred between nodes, allows the mesh network to provide the level of service needed for an AMR operation with very little expense in equipment and hardware.

Another network type is the peer-to-peer network. A peer to peer (or “P2P”) computer network uses diverse connectivity between participants in a network and the cumulative bandwidth of network participants rather than conventional centralized resources where a relatively low number of servers provide the core value to a service or application. Peer-to-peer networks are typically used for connecting nodes via largely ad hoc connections. A pure peer-to-peer network does not have the notion of clients or servers, but only equal peer nodes that simultaneously function as both “clients” and “servers” to the other nodes on the network. This model of network arrangement differs from the client-server model where communication is usually to and from a central server. This type of P2P network can be utilized in the AMR system and be instrumental in providing efficiencies of operation.

Wireless links however, work better when there is clear line of sight between the communicating stations. Wireless mesh nodes deployed over large areas can use the forwarding capabilities of the mesh architecture to go around physical obstacles such as buildings instead of requiring a high power system to transmit through these obstructions. A wireless mesh system will forward transmissions through intermediate nodes that are within range and line of sight and can go around the obstruction operating at much lower power. This mesh net functions very well in dense customer areas with many obstructions and is ideally suited for AMR networks.

Wireless networks can be used to allow access to the Internet over large areas. Large wireless network coverage has been demonstrated in several municipal areas across the United States where hundreds of thousands of network nodes and thousands of access points or gateways have been deployed in these existing networks. However, published reports state that the cost of deploying these wide area wireless network systems is dominated by the cost of the network elements required to connect them to the Internet; these elements together form what is called the backhaul network. The intent of this invention is to make deployable a different type of backhaul network wherein the utility customer itself also contributes substantially to the implementation of the backhaul network.

Utility companies are large enterprises. A typical utility has hundreds of thousands of customers; the largest have several million customers while the smallest have tens of thousands. In addition, these utilities have several thousand employees a large percentage of whom live within the distribution or franchise area of these companies. Also, in a special group of utilities namely the rural electric cooperatives (REC) the customers actually own the company. For example, the largest group of cooperatives, NRECA has over 39,000,000 customers in 47 states. In the case of the large utilities which are normally investor-owned it is potentially possible that several thousand of these employees who are also customers, can profitably help their employers by allowing their existing internet connections to be part of the access points that create the backhaul to the global network. A forward-looking utility company can easily fashion an operational plan that benefits both the company and the customer-employee. In the same vein the RECs have a more pronounced reason being owner-customers to facilitate the utilization of their broadband connections to help the company achieve a better operational profitability. This customer related aspect which contributes to the AMR technology has not been adequately examined in a manner that allows the utilities to be more effective and to deliver their commodities in an efficient and cost effective manner.

Based on the shortcoming in the existing methodologies, there is a need for an AMR system that leverages all the available technologies to simplify installation, operations, monitoring, maintenance and to lower costs while still providing a level of service needed to allow the utility company to meet its service requirements to its customers economically. The subject invention addresses these problems and shortcomings specifically by integrating a set of utility customers as customer supported access points which support a major part of the backhaul network by using their existing Internet connections to connect the mesh network nodes to the global communication network.

### PRIOR ART

The prior art involved in this invention is concentrated mainly in two specific areas: broadband sharing and mesh networks. In the case of broadband sharing or access point sharing between entities, there are many existing systems and technologies that allow Internet users to share their Internet broadband connections between consumers and customers. Some commercially available systems include FON, WHISHER, and SKYPE.

FON (www.fon.com) is a commercial user community that utilizes the user's broadband connection to share his/her access point with the rest of the community of FON users for a fee. The FON system provides an electronic appliance which is a wireless access point that behaves as a router and provides both a private and public access point, and users can share broadband with strangers in exchange for free access to other FON user's access points around the world, or for cash.

WHISHER (whisher.com) is essentially a cooperative metered access point or hotspot system. A customer can use the WHISHER software plug-in and see various hotspots on their computer screen. The WHISHER software plug-in gives consumers an application that instantly aggregates all Wifi networks into one, free global wireless community without requiring new hardware or equipment. Subscribers use the WHISHER software to connect to access points on the WHISHER network.

SKYPE (Skype.com) this system is a peer-to-peer Internet telephony network sometimes referred to as, Voice Over Internet Protocol (VOIP). SKYPE is mainly a piece of free software that lets you make “phone calls” using a microphone and speakers or a headset, using your computer, over the internet using the user's broadband connection, to anyone else who has the SKYPE software installed.

These are among the major commercial applications of the broadband sharing technology that consumers can readily utilize in the market today. These applications have been very successful and target specific end-use areas such as Internet surfing: FON, WHISHER and Internet telephony: SKYPE.

The mesh network prior art is varied and include hardware and software embodiments that vary with industry applications. Specific AMR applications are however more limited.

U.S. Pat. No. 7,312,721 describes a data collector device, comprising: an electronic utility meter that collects and stores billing data related to a commodity consumption; and a network communication device for communicating with downstream utility meters and to a remote location that processes said billing data, wherein the data collector communicates wirelessly with downstream utility meters to read and store billing data contained in the downstream utility meters. The data collector communicates the billing data to a remote location for processing.

U.S. Pat. No. 7,304,587 illustrates a meter reading network system comprising: a plurality of utility meters, a plurality of sensors, a plurality of utility meters, and a plurality of meter data collectors in communication with at least one of the plurality of sensors including a radio frequency telemetry module to transmit the utility usage data and also positioned in radio frequency communication with at least one other of the plurality of meter data collectors.

U.S. Pat. No. 7,058,524 describes a wireless electrical power metering system which contains a processor with multi-channel capabilities, a wireless transceiver, and a power meter attached to measure the power consumption at a location. This power metering system and method also discusses routing the power meter data to a second residence using an external powerline network as the carrier. This method however lacks the mesh hopping capability inherent in the wireless embodiment provided herein in the current application

U.S. Pat. No. 7,020,566 teaches a utility meter comprises an electromechanical metering portion and an electronic portion coupled to the electromechanical portion. This meter is connected to the Internet via a TCP/IP connection.

U.S. Pat. Nos. 7,304,587, 7,312,721 describe networks used in automatic meter reading which include use of wide area networks for communications via field data collectors.

U.S. Pat. No. 6,396,839 provides a metering system electronic metering system, comprising: a wide area network (WAN) operating in accordance with a TCP/IP protocol; a local area network (LAN) comprising a plurality of meters each of which includes meter electronics for measuring a prescribed commodity supplied by a utility and memory for storing measured data and meter control parameters; a gateway operatively coupled to said LAN and said WAN; and an HTTP server operatively coupled to said LAN and said gateway, said HTTP server accessing said measured data, whereby said WAN is provided remote access to said measured data and control parameters of said meters.

U.S. Pat. No. 6,333,975 describes meter reading system which utilizes external modem modules, (EMM) a hub and a data collection system. The EMM communicates with one or more utility meters. The EMM obtains meter data from the utility meter and converts to a radio frequency communication format. The radio frequency formatted data is then transferred to the hub. The hub then translates the radio frequency data into an analog or digital telephone communication format, which is then transferred to the data collection system for use by the utility as desired, e.g. utility billing, tracking, control, etc.

U.S. Pat. No. 6,088,659 describes an automated meter-reading server that collects telemetry data from remote customer locations and processes said telemetry data for use by end users and upstream business systems. The meter-reading server comprises, a data repository to store telemetry data and a system to communicate with external systems and multi-layered distributed software architecture is also implemented on the server.

US2007/0001868 describes a comprehensive mesh network system utilizing sensors, data readers and data collectors, to read, communicate and control meter systems.

US2005/0251403 utilizes a TCP/IP based Wifi network comprising of multiple communications modes, and a communications server to collect meter data.

US2006/0044158A1 describes an AMR device and method which uses a microprocessor, two-way broadband connections forming a wireless network to integrate legacy or existing infrastructure to perform the operations of the utility company without the implementation of costly equipment and services.

US2007/0284293 describes a mesh network system to perform remote AMR operations on a water municipal system.

US2007/0116021 describes a mesh based and a tower based network for communications suitable for AMR operations.

US2008/0002640 provides a communications protocol form use in mesh networks. This protocol can be used to implement AMR operations on a mesh network.

WO 2007/134397 A1 describes an AMR system that collects utility commodity data that utilizes a wired or wireless network to transfer that collected data to a central data storage system.

Eka Systems (www.ekasystems.com) has described a wireless network deployed in Ecuador with 3,600 meter nodes form a network for utility metering. Meter clusters form a network which connects to the central system via access points or gateways.

Patent application 20060044158 provides a very detailed system that is used to form a method and system for AMR operations in which a network is described that utilizes some aspects of wireless mesh networks. It does however have several major operational and implementation shortcomings that need to be addressed and are fully addressed in the specification of the subject invention. In 20060044158, AMR meters connect directly to the Internet. In addition, the aforementioned application also provides for a community access point for communication to the Internet. This community access point (CAP) in the application can be located at the street in front of a residence, on a street light, utility pole, box or other suitable location and connected by fiber or other wire. It further states that this CAP is powered by electrical service at the street and collect meter usage data from several meters within range of the CAP. The application also discusses “daisy chaining” of CAPs in the event one or more CAPs is non functional. There are several problems associated with the various embodiments of this application:
First, the costly need for physically implementing a separate CAP on a separate and remote location to the meter node: the street, a light pole, box, or streetlight.
Second, the need to “run” or install the wire and or fiber to this new location to make it operational.
Third, who shall own this last few feet of fiber or wire? Does the utility; the cable company, the telecom company, the satellite company, the fiber company or the local municipality own it?
Fourth, who pays for the permitting and installation of these last few feet of communication?
Fifth, a further impediment to this intended approach is the need to physically locate an expensive commercial grade router or bridge in a weatherproof outdoor enclosure with antennas at an elevated point in the area at or inside the CAP. This approach is essentially duplicating a communication network system that is already built but unusable because the additional need for the utility to pay the monthly cost of subscribing for each CAP, which is almost as much per customer as the cost of the electric billing itself at typical customer location.

Various cooperative mesh networks have been proposed primarily by academic institutions and community organizations with a limited number proposed by commercial for profit organizations. Among the academic and community groups are, ROOFNET, CUWIN, CSAIL, SOCALFREENET. Commercial groups are: TROPOS, EARTHLINK, BELAIR, ELSTER, METRIX, MERAKI. The academic and community groups focus on open source utilization and available off the shelf hardware, while the commercial groups provide hardware and services with commercial prices usually with proprietary software.

Given the insurmountable problems associated with these above embodiments, there is a need and requirement to find solutions that can address these problems within the framework of existing costs, existing utility regulations and within the culture of the existing utility companies. The use of the existing broadband connections at the utility customer location is a well-defined and easily implemented means of acquiring the services needed to set up a critical portion of the AMR network: the backhaul.

### SUMMARY OF THE INVENTION

The present invention is directed to a system and method for using an AMR mesh network wireless system for collecting and monitoring metering data that includes a plurality of meter nodes, a plurality of access points and a global communications network and a centralized computer server system. The meter nodes communicate usage data from one node to the other through the mesh network by hopping from one node to the other until the usage data is uploaded to the Internet via the access points or gateways. Once the data is on the Internet or global communications network it is readily available to the utility company servers, which are interfaced with this global network. In some circles these access points are sometimes called “hot spots”. In this invention there are at least two types of access points, first, access points implemented and supported by the utility itself and secondly, access points located at the customer site and supported on and by the customer specific Internet connection.

The wireless mesh network is a well-established technology in today's commerce. A typical mesh network allows a plurality of nodes to be connected and these nodes self correct their operations in the event of network trouble. These networks are very robust and allow for a level of redundancy in which any loss can be circumvented without compromising the network operations. In practice, developers and operators of mesh networks concentrate basically on two hardware elements in the network, these are: nodes and the access points or gateways. The nodes are the physical initiating and connecting points in the network and the access points are the physical “windows” through which entry into the global communication network are implemented.

Building and maintaining access points are a major requirement of a viable mesh network. In its simplest form an access point can be considered as a means for entering the Internet or global communication network. Because of the intrinsic features of the global communication network implementation and its inter-connectivity, once any material is “on” the global communication network it is available to any other user. Fundamentally if we can use an existing global communication network connection to input the information to the global communication network, we can make this information available to any one else on the system at a much lower cost of operation.

An embodiment of this present invention is to utilize a subset of the existing Internet connections of the multitude of utility customers as a means of inputting the mesh-derived data to the Internet. By so doing, the customer defined access points support the AMR mesh network at a much-reduced capital cost since the utility will not need to build these access points. A typical utility has hundreds of thousands of customers and it is contemplated in the embodiments of this invention that only a small percentage of these customers are needed to provide adequate Internet access points for the utility mesh network.

In accordance with one aspect of the invention, there is provided a system wherein a small subset of the customers of the utility company forms an integral part of the utility implemented network by providing the AMR data access to the Internet via the customers' existing Internet connections.

In accordance with one aspect of the invention, there is provided a system wherein the customer supported access points can provide for a peer-to-peer network to achieve greater redundancy for the utility.

Furthermore, the customers and their internet connections of these subset members are selected by the utility in a manner that optimizes the operations of the utility network with reference to costs, availability and bandwidth utilization.

Furthermore, the utility selects an adequate number of the customer supported access points necessary to provide a level of operational security and redundancy.

Another feature of the invention, the utility can provide monetary or in-kind contributions to these customers who provide their Internet connections as usable access points.

According to another feature of the invention, a means is provided for implementing an outage notification and display system via the AMR system.

According to yet another aspect of the invention, there is provided a means for disconnecting and connecting the electric current service at the customer location via the AMR system.

Additional features and advantages of the invention will be made apparent from the following detailed description of illustrative embodiments that proceeds with reference to the accompanying drawings.

### BRIEF DESCRIPTION OF DRAWINGS

FIG. 1 is a schematic of a typical AMR mesh network showing the meter nodes with commodity meters, network connections, a global network and the utility company equipment.

FIG. 2 shows schematically and specifically the utility deployed access point and the customer supported access point connected to the global communication network and other customer mesh nodes in the AMR network.

FIG. 3 is a schematic of a typical AMR network showing the inclusion of the two types of access points or gateways, customer supported and utility supported, connected to the global communication network.

FIG. 4 shows schematically a customer neighborhood with the mesh nodes between residents, offices, churches and other locations and the utility deployed and the customer supported access points connected to the AMR mesh network.

FIG. 5 shows schematically interconnected, the customer space, the Internet space and the utility space and the location and implementation of the backhaul portion of the AMR process.

FIG. 6 shows a flow chart of the automatic meter reading process.

FIG. 7 shows schematically the AMR module interfacing with the customer modem and the commodity meter at the customer location and the global communication network.

FIG. 8 shows schematically the mesh network's ability to circumvent physical obstructions in a neighborhood.

FIG. 9 shows schematically the regulatory mandated separation of a typical network interface box at the customer location which connects the customer equipment to his/her service provider network equipment.

FIG. 10 shows schematically a peer to peer network connecting a plurality access points or gateways in the AMR system.

### DETAILED DESCRIPTION

The following description in concert with the associated drawings is intended to convey a thorough understanding of the embodiments described by providing a number of specific embodiments and details that include the features, functionality and advantages of a system and method for Automatic Meter Reading in the utility and associated industries. However, it should be noted, that the present invention and the described embodiments are not limited to these specific embodiments and details, which are exemplary only. It is further understood that one possessing ordinary skill in the art, in light of known systems and methods, would appreciate the use of the invention for its intended purposes and benefits in any number of alternative embodiments, depending upon specific design and other needs.

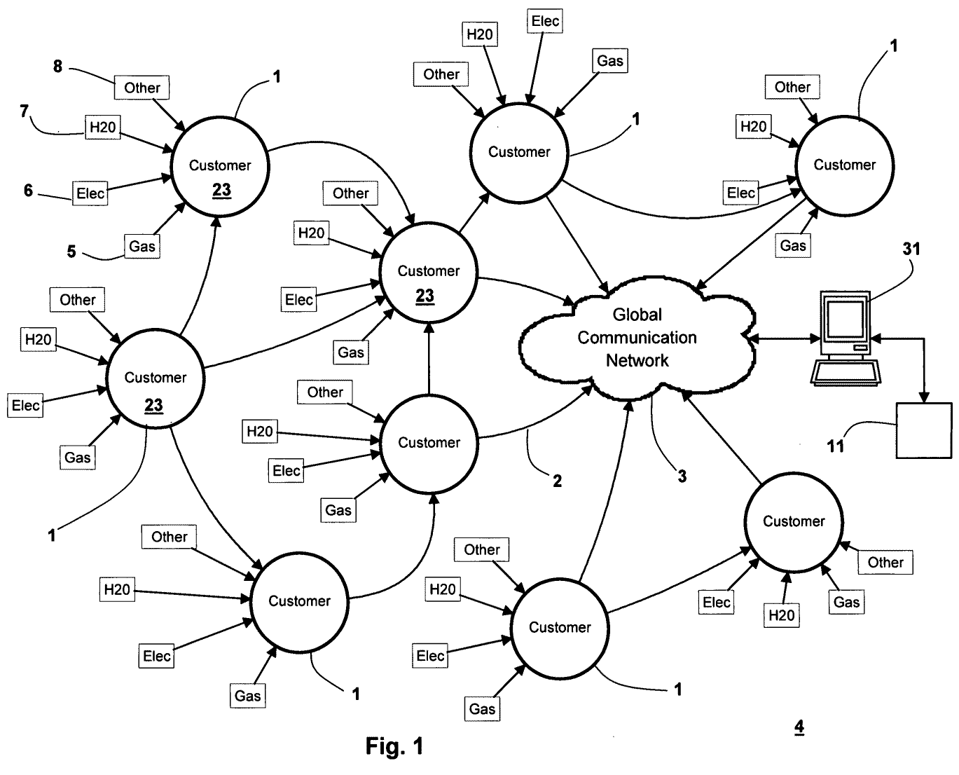

As illustrated in FIG. 1, an embodiment of the present invention provides a mesh network 4 forming the basic infrastructure of the AMR system, including a mesh node 1 at a customer physical site 23 where the commodity usage measurement is determined using a plurality of measuring devices, a gas measurement device 5, an electric usage device 6, water usage device 7 and another device 8 which can measure or monitor other parameters at the customer site. FIG. 1 also shows the interconnection means 2 both between the nodes of the mesh network 4 and the global communication network or Internet 3 and the connection of these elements 1 to the utility company computer system 31 via the global communication network 3. Furthermore, this FIG. 1 shows the presence of a broken connection between a pair of nodes in network, however because of the implicit self-healing nature of mesh networks the network can continue to operate reliably. Also present in the utility computer system 31 is a collection of software and database programs 11 necessary to provide the operational services needed by the utility to function as an ongoing enterprise. The AMR network 4 can be implemented under one embodiment as a public network or it can be set up under another embodiment to be a private network requiring special authentication protocols for each user. A further embodiment can be a combination of private and public elements within the network 4.

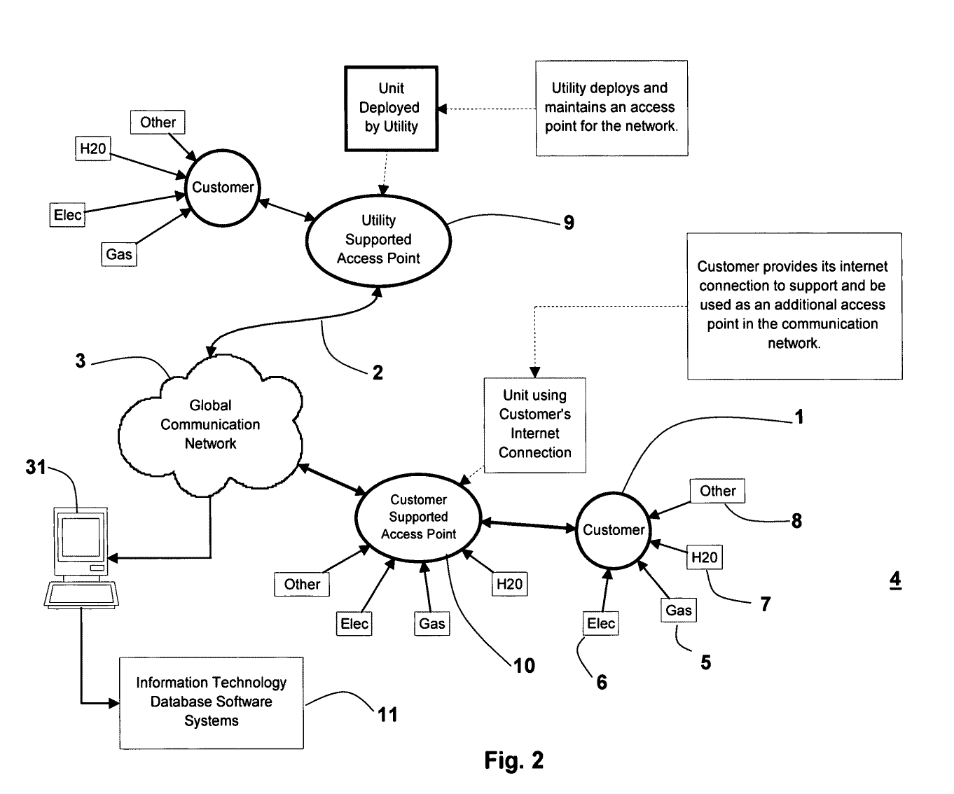

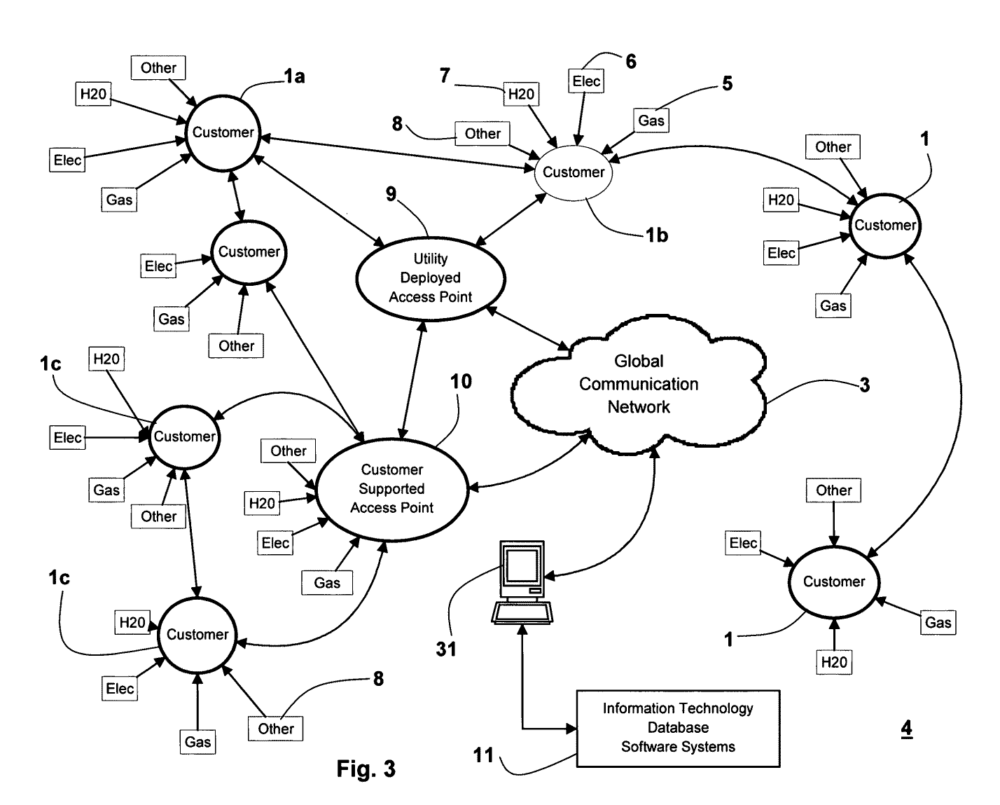

Today, it is essential that data and information collected and accumulated by a company at sites remote from the company home site, reach back to and into the electronic and IT systems of the company. This ability to get actionable information is not limited to the utility industry but it is critical for all major industries and a significant driver that makes all these industries successful is their ability to utilize the functionality of the Internet or the global communication network. Referring to FIG. 2, it is shown that in a mesh network 4, nodes communicate with each other and eventually reach the global network 3 by hopping from one node 1 to another and eventually through an access point 9, 10 or gateway 9, 10. The term access point and gateway are synonymous in this application. In the described embodiment herein the access points 9, 10 are critical to the functionality of the AMR system. The access points 9, 10 are the injection points which allow these measured data to enter the global network 3. FIG. 2 also shows an embodiment wherein there are two types of access points, access points located at the customer site 10, and access points 9 which are deployed by the utility and supported by the utility. FIG. 3 exemplifies how a mesh point 1a transmitting to another customer node 1b which then transmits to a utility access point 9 and finally to the global network 3. This example shows two hops from the initial mesh node 1a to the global network 3. In addition FIG. 3, an embodiment in which a mesh node 1c transmits to a customer supported access point 10, which then transmits to the global network 3. This specific example illustrates a single hop situation. FIG. 3 also shows the access points can communicate with each other bi-directionally; shown in this FIG. 3 is a mutually connected customer access point 10 and a utility access point 9.

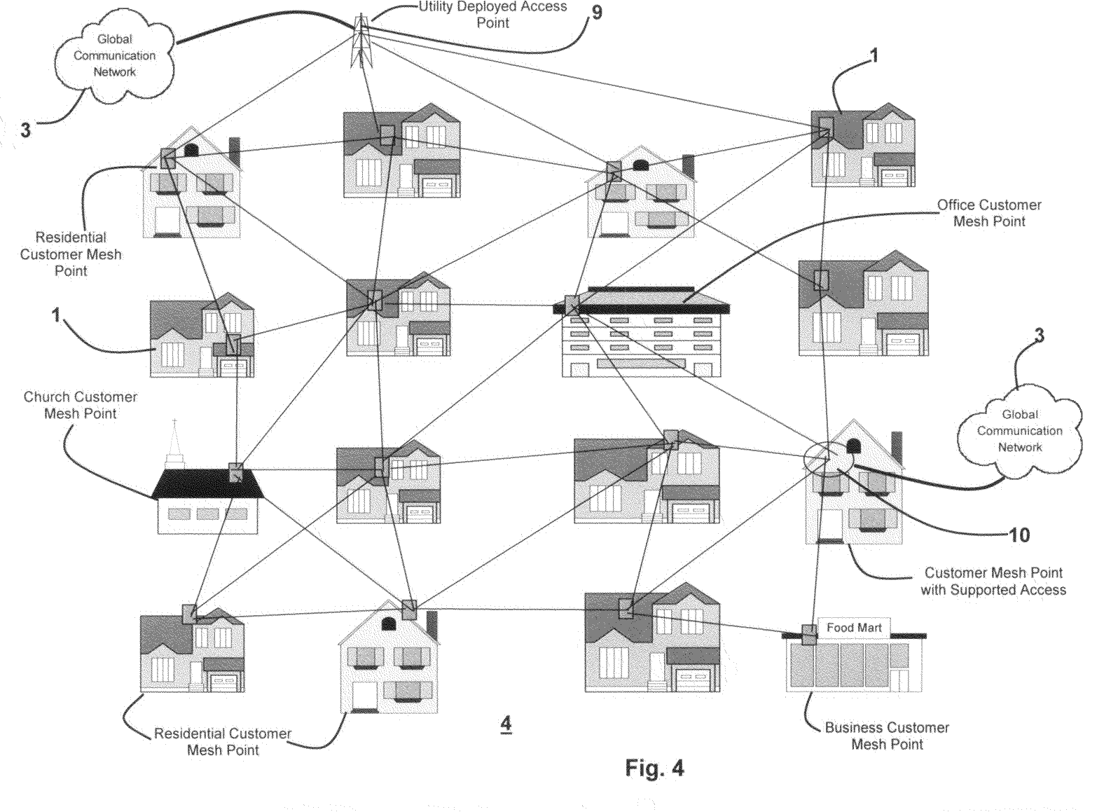

FIG. 4 shows a typical customer neighborhood wherein there is a plurality of different customer structures: family residences, office buildings, churches, businesses and stores, each with a mesh node 1 mutually connected to the network 4. In this FIG. 4 mesh nodes 1 are connected a customer supported access node 10 to the global network 3, similarly shown is the utility-deployed access point 9 connected to the mesh nodes I and the global network 3.

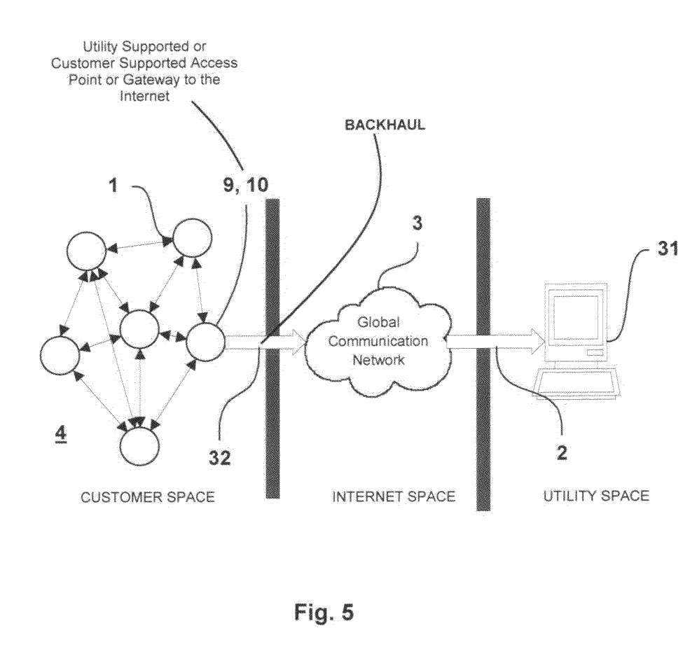

FIG. 5 shows a configuration of an embodiment in which three separate operations spaces or domains are connected to form a continuum in which the AMR system exists. The first space is the mesh network 4, the second space is the global communication network 3 and the third space is the utility space in which the utility computers 31 and information technology (IT) exist. In the mesh network 4, nodal elements 1 interact with each other and are able to transmit data onto the global network through the utility deployed access points 9 or the customer supported access points or gateways 10. Conceptually, there is a requirement in all mesh networks 4 to insert the information carried by these mesh nodes 1 into the global network 3 in a timely and cost effective manner. To achieve, this prior inventions have built separate autonomous networks among them, cellular, wired and wireless to create what is customarily called the “backhaul” in the industry. This backhaul 23 carries the data from the network meshes onto the global system wherein anyone with an Internet-capable computer can interact with the information. In this subject invention an exemplary embodiment describes the connections between the access points 9, 10 and the global network 3 which forms this critical backhaul network.

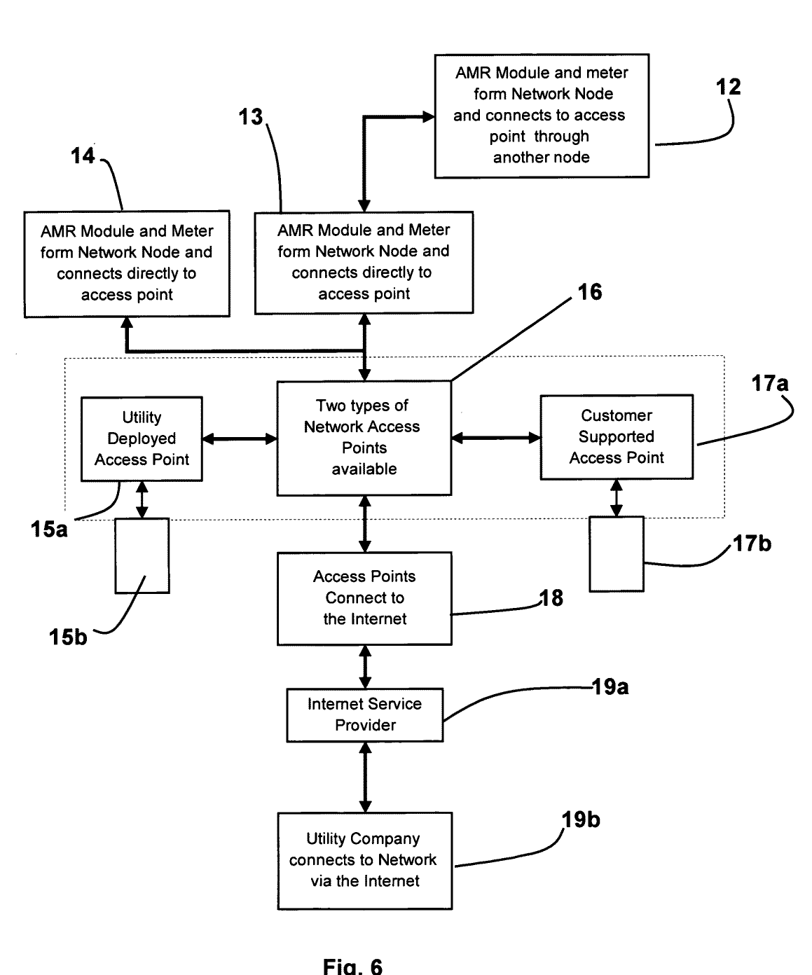

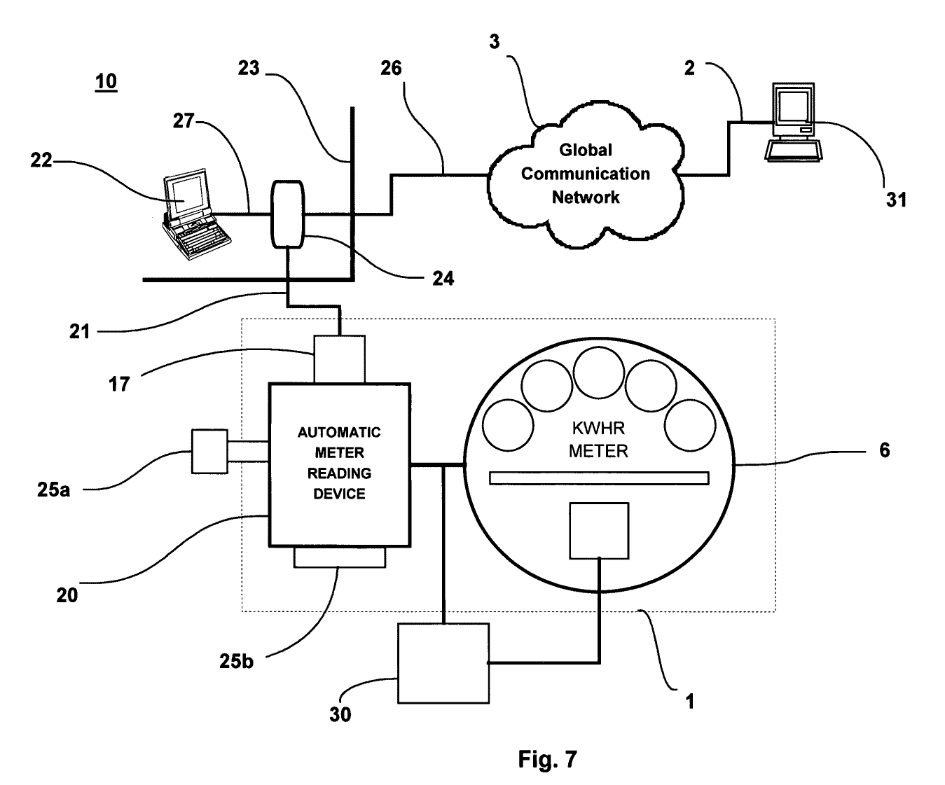

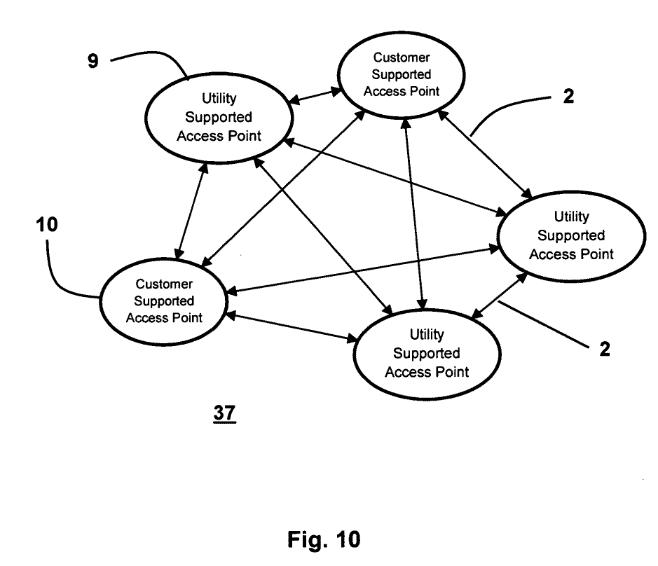

FIG. 6 shows a flow chart of the operations involved in the AMR process. By referring to FIG. 7 an embodiment of the invention shows the detailed implementation at an exemplary customer location 23. It should be noted that there are potentially at least two types of implementations at the customer site. In one simple implementation, the customer site is a generic mesh node 1 in which the AMR data is read, collected and transmitted to other mesh nodes 1 by the AMR module 20 for eventual transmission to the utility location 31. In another more complex implementation, the customer site in addition to reading and collecting its own AMR data, it behaves as an access point or gateway 10 which is used as an entryway into the Internet 3 using the available router or modem 24 at the customer site connected via Internet connection 26. This access point 10 receives information from a plurality of mesh points 1 connected to it across the network 4. In addition these access points 10 are similar in function to the utility deployed access points 9 which provide similar transmission capability to the global network 3. FIG. 10 in addition, shows a further embodiment of this invention wherein these access points 9, 10 can provide a peer to peer network over the Internet which can strengthen the AMR network by allowing a high degree of redundancy for little or no additional investment in hardware since peer to peer networks allow data integration, data sharing and data storage across multiple devices. In this embodiment a plurality of the access points 9, 10 form this ad-hoc type system which allows for bandwidth sharing at times of the day when this type of P2P operation is beneficial to utility operations.

In FIG. 7, further embodiments are shown in which the AMR module 20 has a radio antenna 25a and one or more radios 25b. These radios 25b are utilized to transmit the data from the nodes 1 in the network 4. In this embodiment the AMR module 20 can have one or more radios, a single radio system is cheapest to install but also provides the slowest throughput rate between nodes 1. The multi-radio AMR module 20 offers greater efficiency and data throughput capacity however it is more expensive to install. To offset this radio cost factor an embodiment utilizing more frequently deployed access points 9, 10 with the single radio modules 20 can be utilized to balance cost efficiency and network effectiveness. In an embodiment of this invention an integrated combination of single and multiple radio AMR modules 20 is implemented wherein the low rate single radio AMR modules 20 are preferentially deployed in areas of low volume data transfer, normally on the edges of the AMR network, while the multi-radio AMR modules 20 are implemented in areas of high customer density and high capacity needs. A simple cost-benefit network analysis is made by the utility to provide the necessary deployment types and schedules for a given area. In the exemplary embodiment the radios 25a, 25b transmit over the licensed or unlicensed frequencies. These radio frequencies comprise a plurality of frequencies according to the IEEE 802.11 and IEEE 802.16 standards and also in the ranges 850 to 1000 Mhz, 2.4 to 5.0 Ghz.

The AMR module 20 is implemented in this invention with the means to connect to any of the available commodity meter types, electric, gas or water. Also integral to the AMR module 20 is an embedded microprocessor, providing computational power and also allowing the AMR module 20 the means and ability to encrypt and compress the AMR data before transmission. Available at the AMR module 20 is a means 17 to accumulate identifiable measured AMR data from each of the connecting mesh points. In an exemplary embodiment this means 17 can be implemented in software or hardware. Usually, the electric meters are subdivided into a plurality of types, dumb meters—these simple meters which have no capability to process data; smart meters—these meters have the capability to process and display data; and intelligent meters—which meters are capable of processing, displaying and transmitting data. The AMR module 20 in this embodiment has the means to interface with any of the three types of electric commodity meters. A further embodiment shown in FIG. 7 is the breaker device 30 which provides the AMR module 20 a means to connect and disconnect the electric power supply to the location 23 based on commands from the utility system 31. This ability is a beneficial feature in today's industry where customers relocate routinely and utilities have to make several tens of thousands of “truck runs” annually to physically disconnect and re-connect the meters at customer locations in which several typical “truck runs” can cost the utility hundreds of dollars daily. There are two types of connect-disconnect operations. A “soft disconnect” involves a disruption of billing of the old customer but no shut off of power to the location. A hard disconnect involves a complete shut down of electricity to the premises. The AMR module 20 implements both of these functions.

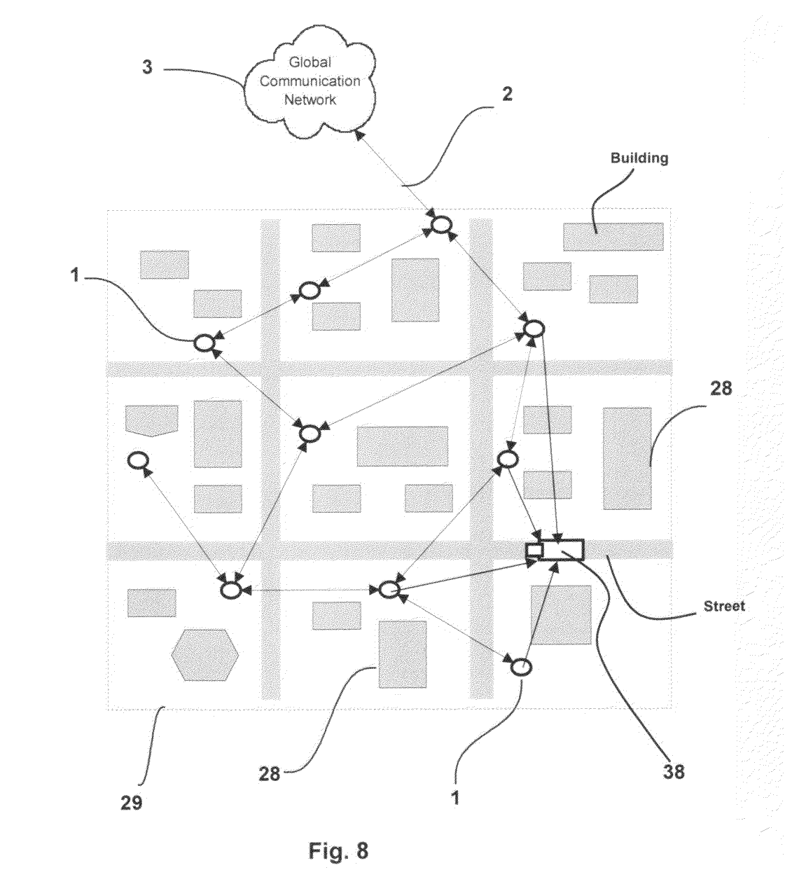

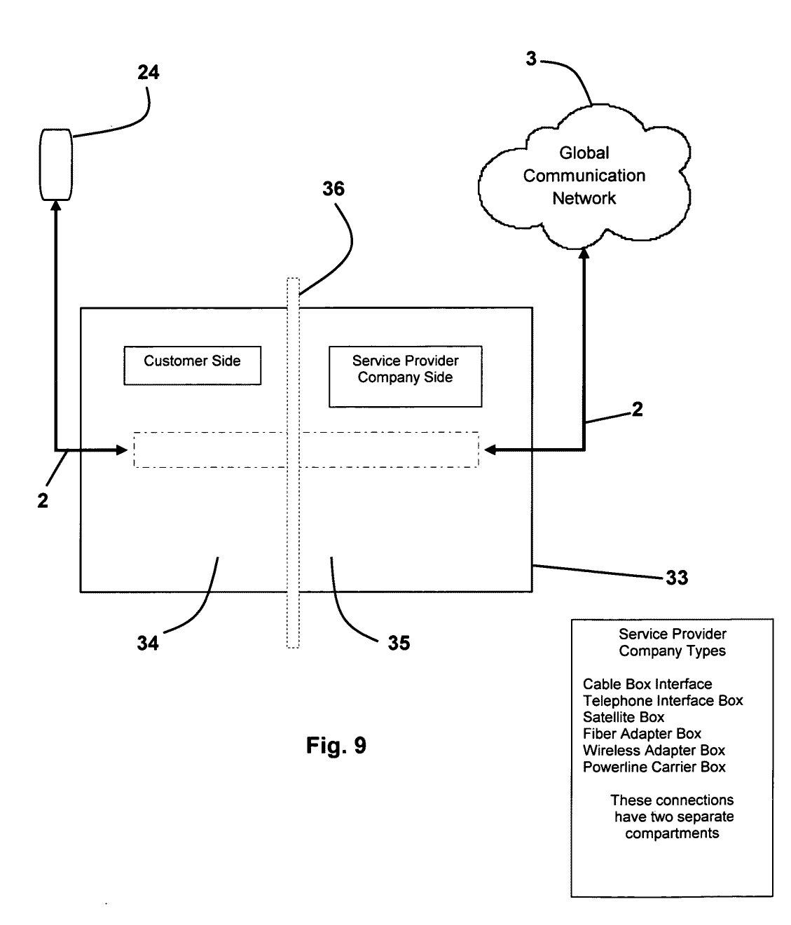

FIG. 8 illustrates the deployment of several mesh nodes 1 in a city or town area with streets laid out in a rectilinear manner. This regular rectilinear development of streets and blocks in most neighborhoods is beneficial to the mesh networks 4 since the transmission can be made laterally and diagonally to communicate around and avoid the buildings in these types of closely spaced urban and suburban developments. Also shown inn FIG. 8 is a mobile access point 38 which can be a utility company vehicle or a utility company controlled vehicle. In FIG. 9 a communication interface box 33 of the type commonly used in the industry today is illustrated. This element is the last few inches of the public network in today's communication industry. By regulation each box 33 is divided into two compartments, the first 34 is the customer side and the second 35 is the service provider side. There is a physical divider 36 between these two sides. By regulatory law, the customer has complete and absolute dominion on what ever happens on their side 34 of the box, he/she can add equipment, devices and other modifications as long as they meet existing FCC requirements. On the customer side are routers, modems, adapters and other electronic devices. This ability allows the customer to be an independent entity and be able to innovate his equipment as needed without the need for permission and oversight by the communications provider as long as the customer installed products meet FCC requirements for interconnection to the public networks. These are usually Part 15 and Part 68 requirements. It should be noted that there exists an acrimonious economic battle between the various communication providers today for the Internet, telephone and cable TV business of the consumer customer. This battle for customers literally occurs before the customer compartment 34 of the communications interface, therefore once the customer has made the decision to select a provider the decision is made and the AMR system implementer, the utility, does not have to be involved or be embroiled in any litigations or legal struggles between Cable, DSL or Satellite carriers. In addition, some Internet service providers (ISP) try to limit and control the volume of traffic or capacity on the customer's connection, this is not a major problem contemplated by the subject AMR embodiments illustrated herein by this invention since the volume of traffic for AMR meters is extremely small and provide no threat to the customer capacity limits in today's communication industry.

According to an exemplary embodiment of this invention the utility company installs the AMR modules 20 at the customer locations 23. The utility connects the AMR module 20 using customarily available devices to the gas commodity meters 5, electric power commodity meters 6 and water commodity meters 7, also in some situations other parameter measuring devices 8 are optionally installed. Using widely available network design models the utility determines the topology and deployment of the mesh nodes 1 and the number and locations of the access points or gateways 9, 10. As an integral part of this network design the utility has to optimize the combinations of mesh points 1 and access points 9, 10 needed to meet the requirements to read the meters 5, 6, 7 and provide data to the utility in an most advantageous manner.

A major departure from existing inventions and technologies is advocated in this subject invention since many prior inventions have focused on a separate costly physical backhaul system. By implementing the customer supported access points 10 as provided herein, the utility has a significant advantage. There is no need, nor major capital costs in building a complete new network to backhaul data, the customer Internet connections 26 are already in existence and connected to the Internet 3. In determining the customer access point 10, it should be noted that the typical utility has several thousand employees who are also commodity customers of their utility employer. No better selection of access point candidates is available than to have a company employee “volunteer” their existing Internet connection to be a customer supported access point 10. This novel approach is forward looking technique in which a utility can achieve a level of operational service and a significant comparative advantage over its competitors.

For example, a utility with 5,000 employees across its region can very easily obtain from its personnel, a group of 1,000 to 2,000 of its employees who are sufficiently sophisticated to have broadband Internet connections at their homes. This group of 1,000 customers will reasonably cover a large geographical area or portion of the utility's distribution region. By using these thousands of customers as appropriate entry points 10 the utility has the need for only a reduced number of more expensive utility deployed 9 access points. In some rare cases, it may be possible that there may no need for utility deployed access points 9. It is contemplated herein that the utility can pay a small stipend to each of these access point 10 owners to compensate for the very small amount of Internet bandwidth consumed. The fractional bandwidth use is very small since the data transmission by the AMR modules 20 is so small that it creates minimal load on the customer's connection. For example, on a cost basis, paying a nominal $10 usage fee per month to a customer for the usage of the internet connection to each of 1,000 customers is a relatively small expense, equaling $120,000 annually, for a utility which is accustomed to paying several tens of millions of dollars annually to perform its meter reading services and to build and maintain a separate backhaul network for AMR services. This total stipend is equal to a single mid-level manager's annual salary and overhead expenses today. Furthermore, this nominal stipend can be credited seamlessly into the customer's account during the billing process with little accounting overhead since most existing billing systems have means for crediting and debiting forward or backward additional customer fees. Any possible legal ramifications from paying the customer for the use of the access point 10 can be negotiated with the ISP since most subscriber agreements do not allow reselling services. Whether connecting the access point 10 router to the AMR module 20 can be considered reselling in the normally industry accepted sense is still an open legal question. A further embodiment is provided wherein this potential legal problem can be overcome. In this exemplary embodiment, the AMR module 20 which may be legally or contractually constrained from connecting directly to the customer modem 24, can connect instead to the existing customer's personal computer (PC) 22 by available wired or wireless means, including Bluetooth, Zigbee, or directly to an USB port on the PC 22. In this embodiment the AMR data from the AMR module 20 is now transferred to the customer PC 22 and by using a simple software program this AMR data file is transmitted to the utility 31 via the customers Internet connection 26 using available transfer protocols like FTP. In this manner the AMR data and the AMR module 20 does not violate any agreements with the communication providers. This unlikely legal situation is not considered to be a major problem however.

Additional access points above the number offered by the customer supported sources can be implemented by utility deployed sites 9 or optionally by using non-utility customers or other opportunistic individuals or companies who are willing to allow the utility to use their Internet connections for a fee or for some in-kind contribution. Further, utilities in general have a massive fleet of vehicles ranging in size from large trucks to midsize trucks and personnel motorcars. Companies like U-Connect have provided mobile hotspots which can be deployed by the utility in a plurality of its vehicles to provide mobile access points 38 for the network 4. Operationally, these utility vehicles are usually parked in a neighborhood for several hours while the linemen and workers are working on field operations, during these periods and while traveling to and from these locations these mobile access points 38 can easily supplement the utility network access points.

The installation of the access point 10 equipment which includes the AMR module 20 along with its antenna 25a and radio 25b is a simple task easily implemented by existing utility personnel. The AMR module 20 is connected to the customer's Internet modem or router 24 by a wired or wireless connection 21. Also present in the subject embodiment is the means 17 for accumulating data at the AMR module 20 before the data is transmitted. The combination of the mesh nodes 1 and the access points 9, 10 along with the AMR modules form the network infrastructure for the invention.

Operationally in an embodiment as illustrated in FIG. 6, as shown in step 12 the AMR module 20 reads data at the meter 5, 6, 7 and send this data as shown in step 13, by hopping along the mesh network 4 from one mesh node 1 to the another mesh node 1 until an access node or gateway 9, 10 is reached. As shown in step 14, the data from AMR module 20 can reach the access point 9, 10 directly with hopping. As shown in step 15a the data is transmitted through the utility access point 9 where it can also be accumulated in step 15b. Similarly in step 17a the data is transmitted through the customer supported access point 10 where the data can also be accumulated before transmission. As shown in step 18 the meter data is transmitted via a customer supported access point 10 or via a utility supported access point 9 to the global communication network as illustrated in step 18 where an internet service provider shown in step 19a is the communications organization that provides internet services. In step 19b the utility computer system 31 connects to the Internet 3 and obtains the meter data which is now available online via the global communication network.

The systems and methods have been described, discussed and illustrated with reference to specific embodiments and drawings, however those skilled in the art will recognize that other modification and variations of the invention may be made without departing from the principles described above and set forth in the following claims.

The following claims more fully describe the true scope and spirit of disclosed embodiments.

| | List of Items |
|---|---|
| 1a, 1b, 1c | Customer node in mesh network |
| 2 | Interconnection means - wireless or wired |
| 3 | Global Communication Network or Internet |
| 4 | Mesh Network |
| 5 | Gas Usage commodity device |
| 6 | Electric Usage commodity device |
| 7 | Water Usage commodity device |
| 8 | Other Usage device |
| 9 | Utility Deployed access point |
| 10 | Customer supported access point |
| 11 | Utility database and software |
| 12 | Meter node connected to another node |
| 13 | Meter node dually connected directly to access point and other |
| | mesh point |
| 14 | Solitary Meter node connected directly to access point |
| 15 | Data accumulator at utility deployed access point |
| 16 | Two types of access points |
| 17 | Data accumulator means at customer supported access point |
| 18 | Access points connected to the internet |
| 19 | Internet Service Provider |
| 20 | Meter node AMR module |
| 21 | AMR connection to Customer modem |
| 22 | Customer PC at customer location |
| 23 | Customer location e.g residence, office |
| 24 | Customer modem or router |
| 25a | Antenna on AMR device to transmit to other mesh nodes |
| 25b | Radio on AMR device node |
| 26 | Customer modem connection to the Internet |
| 27 | Customer PC connection to modem |
| 28 | Building location |
| 29 | Portion of utility service area |
| 30 | Breaker device for disconnection of meter |
| 31 | Utility computer server system |
| 32 | Backhaul link to global communication network |
| 33 | Generic Communication Interface box at customer location |
| 34 | Customer side compartment of Interface Communication Box |
| 35 | Company side compartment of Interface Communication Box |
| 36 | Regulatory mandated separation in Network Interface Box |
| 37 | Peer to peer network |
| 38 | Mobile access point |
| AMR | Automatic Meter Reader |
| AP | Access Point or Gateway |
| CAP | Community Access Point |
| FTP | File Transfer Protocol |
| GCN | Global Communication Network or Internet |
| IEEE | Institute of Eleclrical and Electronic Engineers |
| IT | Information Technology |
| KB | Kilobyte |
| MB | Megabyte |
| NRECA | National Rural Electric Association |
| P2P | Peer to peer |
| PC | Personal Computer |
| PLC | Power Line Carrier |
| REC | Rural Electric Cooperative |
| RF | Radio Frequency |
| TCP/IP | Terminal control program/.Internet protocol |

We claim:

1. A method of providing automatic meter reading (AMR) and customer services by a utility, the method comprises:
(a) implementing a network comprising a plurality of AMR devices or nodes at customer locations,
(b) implementing a plurality of access points in said network, wherein the step of implementing the access points comprises the substeps of:
providing means for implementing a plurality of access points using selected utility customer locations wherein these customers are employees of the utility,
providing means for implementing a plurality of access points using selected utility customer locations wherein these customers are not employees of the utility,
providing means for implementing a plurality of access points using utility constructed locations.
(c) connecting said network access points to a global communication network, wherein the step of implementing said access points further comprises the substeps of:
selecting a plurality of customer nodes to provide a subset of collocated access points at their meter locations,
recruiting and utilizing a plurality of the utility employees who are customers, to provide an employee supported subset of said collocated access points at their meter locations,
recruiting and utilizing a plurality of the non-employee utility customers to provide a subset of said collocated access points at their meter locations,
constructing and utilizing a plurality of the utility controlled locations forming a subset of said access points.
(d) determining the commodity usage with the AMR devices,
(e) transmitting said commodity usage data from the customer AMR devices to the utility company over the network via the access points; wherein the step of implementing said transmission of commodity data further comprises the substeps of:
hopping the data from one node to another in the network,
receiving the data at a node that has a collocated access point,
introducing this data onto the global communication network via said collocated access point
receiving said data at the utility via the global communication network.
(f) collecting and utilizing this commodity usage data at the utility company,
(g) providing a means for implementing operational services between the utility and its customers via the network.

2. The method of claim 1 wherein the network is a mesh network comprising a plurality of nodes.

3. The method of claim 1 wherein the network is wired or wireless.

4. The method of claim 1 wherein a means is implemented to remunerate the customer for implementing and usage of the collocated access point.

5. The method of claim 1 wherein a means is implemented to remunerate the utility employee for implementing and usage of the collocated access point.

6. The method of claim 1 wherein a plurality of access points are supported directly by the utility.

7. The method of claim 1 wherein the AMR devices are addressable.

8. The method of claim 1 wherein the access points are addressable.

9. The method of claim 1 wherein the access points are fixed.

10. The method of claim 1 wherein the access points are mobile.

11. The method of claim 1 wherein the number of access points is between ½ percent and 10 percent of the total number of network nodes.

12. The method of claim 1 wherein the operational services provided comprise, time of use information, remote control of appliances, “on and off” control, outage detection, remote connect and disconnect services, alarms, power usage and tampering information.

13. The method of claim 1 wherein the access points are connected to the Global Communication Network by a plurality of means comprising, DSL, cable, FIOS, telecom, satellite, wired and wireless links.

14. The method of claim 1 wherein the commodity usage comprises, electric power usage, natural gas usage, water usage, internet usage, cable TV and telecommunication usage.
